(19) United States
(12) Patent Application Publication
(10) Pub. No.: US 2013/0299966 A1
(43) Pub. Date: Nov. 14, 2013

(54) WSP DIE WITH OFFSET REDISTRIBUTION LAYER CAPTURE PAD

(71) Applicants: Anil KV Kumar, Bangalore (IN); Gary Paul Morrison, Garland, TX (US)

(72) Inventors: Anil KV Kumar, Bangalore (IN); Gary Paul Morrison, Garland, TX (US)

(73) Assignee: Texas Instruments Incorporated, Dallas, TX (US)

(21) Appl. No.: 13/469,012

(22) Filed: May 10, 2012

(51) Int. Cl. H01L 23/48; H01L 21/60

(52) U.S. Cl. 257/737; 438/613; 257/E23.021; 257/E21.506

(57) ABSTRACT

A WSP die having a redistribution layer (“RDL”) with an RDL capture pad that has an RDL pad central axis RR and a RDL pad outer peripheral edge arranged about the RDL capture pad central axis RR and an under bump metal (UBM) pad positioned above the RDL capture pad. The UBM pad has a UBM pad central axis UU and a UBM pad outer peripheral edge arranged around the UBM pad central axis UU. The UBM pad central axis UU is laterally offset from the RDL pad central axis RR.

### BACKGROUND

Integrated circuits, also referred to as “IC's” or “semiconductor chips” or simply “chips,” are electronic circuits made by diffusion of trace elements into the surface of thin substrates of semiconductor material such as silicon. Semiconductor chips are typically mass produced in the form of a single wafer that contains a large number of identical integrated circuits. The wafer is cut (“singulated”) into a number of individual semiconductor chips referred to as “dies” or “dice.”

Dies are usually “packaged” to prevent damage to the dies and to facilitate attachment of the dies to circuit boards. Various packaging materials and processes have been used to package integrated circuit dies. One conventional packaging method involves mounting individual dies in a predetermined pattern on a substrate strip. The dies mounted on the substrate strip are then encapsulated in a protective material such as plastic. The encapsulated dies are next singulated into individual integrated circuit packages by cutting the encapsulated die/substrate strip in accordance with the predetermined die mounting pattern. Typical cutting tools include saws and punches. Each integrated circuit package generally includes at least one die and the underlying portion of the substrate strip on which it was mounted, as well as encapsulating material which typically covers the die. The underlying substrate strip is sometimes a lead frame to which the die is electrically connected and which, in turn, is adapted to be connected to a printed circuit board (“PC” board).

Over the years, integrated circuits and the circuit boards to which they are attached have become physically smaller and more complex. One relatively new technology is known alternately as “wafer scale packaging,” “wafer level chip scale packaging,” “wafer level chip size packaging,” or other similar names. The phrase “wafer scale packaging” (“WSP”) will be used herein. Using WSP packaging, unpackaged dies, i.e., dies with no surrounding layer of protective encapsulation, may be directly mounted on printed circuit boards. The structure needed for electrical connection of dies to a printed circuit board is usually fabricated on a first surface of the dies while the dies are still integrally connected together in a single wafer. For example, in one form of WSP packaging, various layers including electrical contact pads, solder bumps and intermediate layers are formed on a first surface of dies at the wafer level. WSP eliminates conventional packaging steps such as die bonding, wire bonding, and die level flip chip attach processes to a package substrate by using the IC die itself as the electrical connection substrate. Use of the die itself as the WSP substrate significantly reduces the footprint to the IC die as compared to the same IC die attached to a package substrate.

WSP can be embodied as direct-bump WSP or redistribution layer (“RDL”) WSP which unlike direct-bump WSP adds an RDL that functions as a rewiring layer. This rewiring layer enables repositioning of external terminals at desired positions. (A redistribution layer is sometimes referred to in the art as a “redirect layer.”)

In a typical RDL WSP production flow, during back end of the line (BEOL) wafer fab processing, the IC die is provided with die pads (also known as bond pads or die bond pads) and a passivation layer. A first WSP dielectric (e.g., a polyimide) is then deposited over the passivation layer and die pads. Lithography/etching are used to form first vias in the first WSP dielectric over the die pads, followed by deposition and patterning of an RDL, including a plurality of RDL traces, which contact the die pads and extend laterally therefrom. A second WSP dielectric (e.g., a polyimide) is then deposited on the RDL and second vias are formed that reach the RDL in RDL capture pad positions. The positions of the RDL capture pads are laterally spaced from the positions of the die pads. Under bump metallization (UBM) pads commonly referred to as “ball pads” or “bump pads” are formed over the second vias and are coupled to and generally enclosed by RDL capture pads, followed by forming metal (e.g., solder) balls, pillars or other bonding connectors on the UBM pads. The area of the RDL capture pads is generally larger than the area of the UBM pad thereon to absorb stresses and thus improve structural reliability. The WSP wafer is singulated to form a plurality of singulated WSP die, commonly for use on circuit boards for portable devices where the board area is precious.

### BRIEF DESCRIPTION OF THE DRAWINGS

FIG. 1 is a cross sectional view of a WSP die having an under bump metal (“UBM”) pad which overhangs a redistribution layer (“RDL”) capture pad;

FIG. 2 is a cross sectional elevation view of a WSP die having an RDL capture pad which is radially offset relative to an under bump metal (“UBM”) pad;

FIG. 3 is a top plan view of portions of two layers of the WSP die of FIG. 2, showing the relative position of the RDL capture pad and the UBM pad positioned above it;

FIG. 4 is a cross sectional view of the WSP die of FIG. 2, showing propagation of a crack through a second dielectric layer; and

FIG. 5 is a flow chart of a method of making a WSP die.

### DETAILED DESCRIPTION

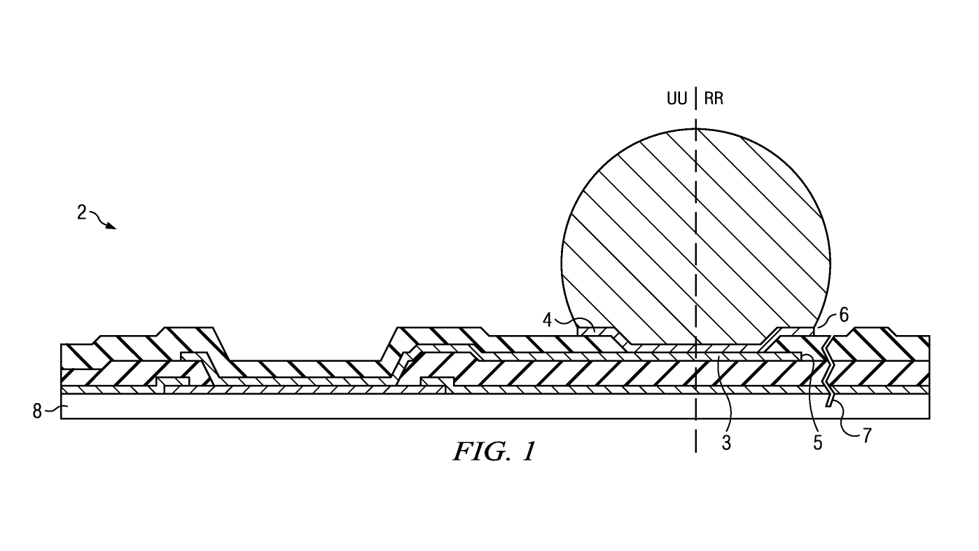

WSP dies (also referred to as WSP “chips”) are often connected to external circuitry, e.g. printed circuit (“PC”) boards, wiring substrates or other chips, using ball grid arrays. A ball grid array is formed on a front (top) face of each die and is placed in electrical contact with corresponding connectors on the external circuitry. WSP dies that have such ball grid arrays are sometimes referred to in the art as “flip chips” because the ball grid array is simply “flipped over” to a front (top) face down orientation to connect it to the external circuitry. In designing WSP dies with ball grid arrays there are conflicting considerations. The size of each ball, and thus the diameter of the under bump metal (UBM) layer to which the ball is attached, cannot be reduced because of mechanical reliability considerations. However, large balls are generally undesirable when the balls carry RF signals because the associated large UBM layer and corresponding large redistribution layer (RDL) capture pad to which the UBM is attached create capacitance related parasitic effects. These parasitic effects manifest themselves in lower transmission power, poorer signal matching, and/or lower band width of operation, etc. for a typical wireless transceiver. In typical WSP dies the RDL capture pad has a larger footprint than the UBM pad. Reducing the size of the RDL capture pad would reduce the capacitance/parasitic effects. However, reducing the size of the RDL capture pad creates other problems as illustrated by FIG. 1. FIG. 1 is a cross sectional elevation view of a portion of a WSP die 2. The WSP die has a RDL capture pad 3 which terminates at an outer peripheral edge 5. The WSP die 2 has a UBM pad 4 which is positioned above and contacts a portion of the RDL capture pad 3. The UBM pad 4 has an outer peripheral edge 6 which extends radially outwardly beyond the entire outer peripheral edge 5 of the RDL capture pad. Using a construction such as shown in FIG. 1 a serious cracking problem may occur. Cracks, such as crack 7, often form near the outer peripheral edge 6 of the UBM pad 4. Crack 7 may propagate downwardly, unimpeded, through various die layers below the UBM, passing the RDL peripheral edge 5, and ultimately entering silicon substrate 8. The crack 7 may thus damage transistors and/or other electronics in the silicon substrate 8 as well as rupturing and weakening the die surface layers. Applicants have designed a WSP die with a relatively smaller RDL capture pad, where the above described cracking problem is considerably reduced, and wherein RF transmission may be improved.

In describing the various features of a WSP die, applicants have used terms of positional/directional reference such as “up,” “down,” “bottom”, “top,” “above,” “below,” “lateral” and “vertical” which are sometimes used in reference to an orientation with respect to the surface of the earth. Such terms are not used in that sense in this application. Rather, terms such as up, down, etc. are used in a relative sense to indicate the position of a die layer or surface, etc. with respect to other layers or surfaces, etc. in a structure which initially is oriented as shown in the drawings. As used in this sense the “top” of a car would still be referred to as the “top” of the car, even when the car is subsequently positioned upside down in a ditch. Also, it will be understood by those skilled in the art that, for the most part, various layers of a die are arranged in parallel planes that are separated vertically, i.e., in a direction perpendicular to the planes, by very small distances, e.g. 0.1-10 μm. When a first layer is positioned over a second layer in this manner, a portion of the first layer, which projects laterally outwardly from a vertical projection of the second layer that is superimposed onto the first layer, will simply be referred to as projecting laterally outwardly from the second layer and vice verse, even though the two layers are positioned in different planes.

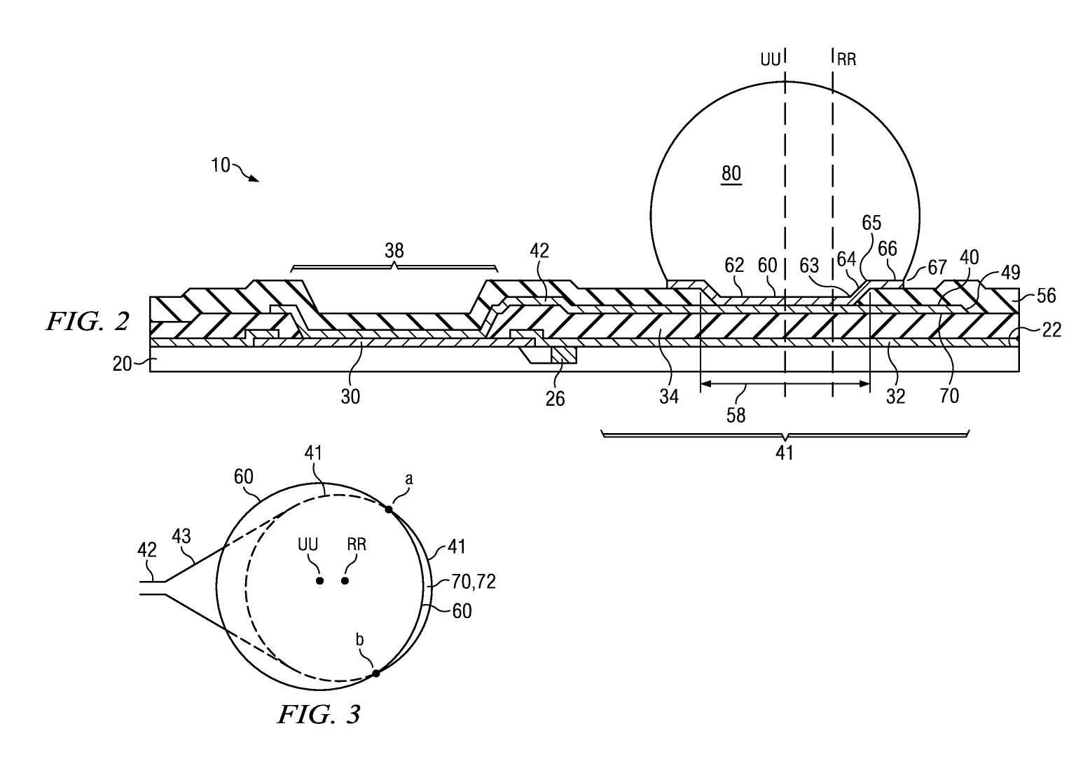

FIGS. 2-4, in general, illustrate a WSP die 10 having an RDL capture pad 41 with an outer peripheral edge 49 and a UBM pad 60 having an outer peripheral edge 67. The central axes RR and UU of the RDL capture pad 41 and UBM pad 60 are radially offset. In some embodiments the outer peripheral edge 67 of the UBM pad defines an area larger than the area of the RDL capture pad 41. In one such embodiment the area defined by edge 67 is at least 2.8% larger than the area of the RDL capture pad 41. The UBM pad 60 is positioned above the RDL capture pad 41. In one embodiment the centers of the RDL capture pad and the UBM pad are offset a distance of between 5% and 12% of the radius of the RDL capture pad. A portion of the RDL capture pad outer peripheral edge 46 is positioned laterally (radially) outwardly of the UBM pad outer peripheral edge 67. Making the area of overlap between the RDL capture pad and the UBM pad smaller reduces capacitance related parasitic effects and thus improves RF performance as compared to an assembly having a larger RDL capture pad/UBM pad overlap area. In one embodiment, as best shown in FIG. 3, a portion 70 of the RDL capture pad 41 extends laterally (radially) farther than the outer peripheral edge 67 of a UBM pad 60. This protruding portion 70 provides improved structural integrity over RDL capture pad/UBM pad assemblies, such as described with reference to FIG. 1 above, that has no such RDL protruding portion 70. In one embodiment, the area of protruding portion 70 is at least 2.8% of the total area of the RDL capture pad 41. The protruding portion 70 may be oriented such that it is positioned in an area that is most susceptible to cracking. The location of this protruding portion 70 will vary depending upon the location of the ball in the ball-grid-array. Having thus described WSP die 10 generally, further details thereof will now be described.

FIG. 2 illustrates that WSP die 10 has a semiconductor substrate 20, which may be a silicon substrate. The substrate 20 has an upper surface 22 and internal circuitry 26. A metal die pad 30 is formed on the substrate upper surface 22. The metal die pad 30 may be made from, for example, copper, aluminum, or gold. A passivation layer 32 is also formed on the substrate upper surface 22. The passivation layer 32 extends laterally from the metal die pad 30. In the illustrative embodiment of FIG. 2, a small portion of the passivation layer 32 extends up and over a peripheral edge portion of the die pad 30. The passivation layer 32 may be made from, for example, silicon nitride. A first dielectric layer 34, which may be a polyimide layer, is positioned over the metal die pad 30 and passivation layer 32. A first via is formed through the first passivation layer may be an inverted, truncated-cone shaped via that exposes the metal die pad 30 through the first dielectric layer 34. The place where the via is formed is indicated at 38. A redistribution layer (RDL) 40 is applied on top the first dielectric layer 34 and in one embodiment may be generally “tadpole” shaped, FIG. 3, having a circular RDL capture pad 41, and a narrow, laterally extending RDL lead 42 connected to the RDL capture pad 41 by a generally triangular RDL transition region 43. The RDL lead 42 extends into contact with the upper surface of metal die pad 30, thus electrically connecting the metal die pad 30 with the RDL capture pad 41. The RDL 40 may be made from, for example, copper. Returning to FIG. 2, a second dielectric layer 56, which may be a polyimide layer, is formed on top of the RDL 40 and also on top of a portion of the first dielectric layer 34, which extends beyond the RDL 40. A generally inverted, truncated-cone shaped via that extends through the second dielectric layer 56 is then formed at a position illustrated at 58. The via extends through the second dielectric layer 56 to the RDL layer capture pad 41.

Referring to FIG. 2, an under bump metal (“UBM”) pad 60 is formed on top of the exposed area of the RDL capture pad 41 and an annular portion of the second dielectric layer 56. The UBM pad 60 thus includes a circular, radially extending central portion 62 and annular sloped portion 64 connected to central portion 62 at transitional line 63. The UBM pad 60 further includes an annular, radially extending portion 66 which terminates at an outer peripheral edge 67. An annular connection line 65 is formed where sloped portion 64 and radially extending portion 66 meet. The UBM 60 may be made from, for example, copper. A solder ball 80 or other connector may be attached to the UBM pad 60.

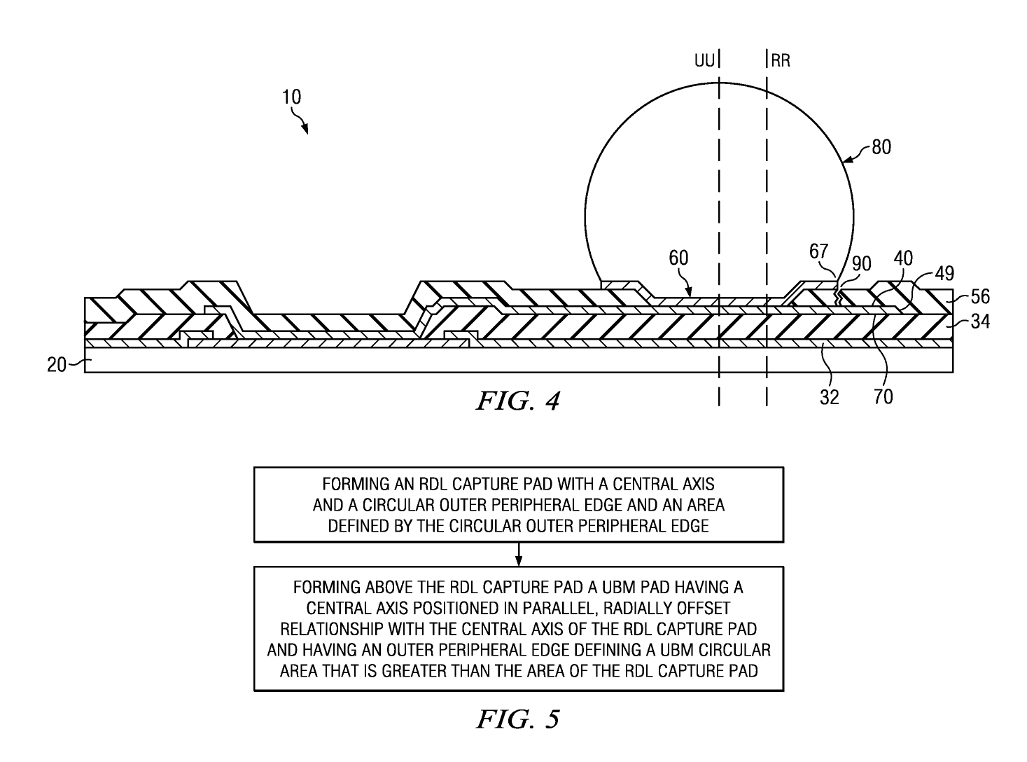

A top view of the UBM pad 60 and its relative position with respect to RDL 40 is illustrated in FIG. 3. As best shown by FIGS. 3 and 4, the RDL layer 40 has a capture pad 41 with an outer circular periphery 49 which lies mostly inside of UBM pad outer edge 67. A small crescent shaped portion 72 of RDL pad 41 does not lie inside UBM outer edge 67. This crescent shaped portion is defined by the two arcs extending between vertical axes “a” and “b” in FIG. 3. The outer arc is a portion of peripheral edge 49 of the RDL pad 41. The inner arc is a portion of the outer peripheral edge 67 of the UBM pad 60. Peripheral edges 49 and 67, in the embodiment shown in FIGS. 2-4 are both circular. However these peripheries may have different shapes and sizes than the ones shown in FIG. 4. For example the peripheries could be polygonal or oval.

One advantage of having a portion 70 of the RDL capture pad 41 projecting beyond the periphery 67 of the UBM pad 60 is illustrated in FIG. 4, which shows a die 10, as illustrated in FIG. 2, in which a crack 90 has formed in the second dielectric layer 56 near the periphery 67 of the UBM 60. Because of the greater lateral extension of the RDL capture pad 41, a crack 90 beginning in the second dielectric layer 56 propagates only as far as the RDL capture pad 41 laterally outwardly projecting portion 70 where it is halted. In the embodiment of FIG. 1, in which the UBM pad overhangs the peripheral edge 5 of the RDL capture pad 3, there is no RDL present to stop the propagation of crack 7. The crack 7 thus continues to propagate downwardly into the silicon substrate 8.

FIG. 5 illustrates one embodiment of a method of making a WSP die. The method includes, as shown at 101, forming in a redistribution layer (“RDL”) in an RDL pad that has an RDL center point. The method further includes, as shown at 102, forming, above the RDL pad, a UBM pad that has an outer periphery arranged around a UBM center point that is radially offset from the RDL center point.

Although in the illustrated embodiment, the RDL capture pad 41 and UBM pad 60 each have a circular outer periphery, in other embodiments the structures may have polygonal or other shapes so long as the central axes RR, UU thereof are radially offset. In some embodiments the portion of the RDL capture pad 41 positioned below the UBM pad 60 has a smaller area than the outer peripheral edge of the UBM pad 60 and a portion of the RDL capture pad projects outwardly from the area of overlap with the UBM pad. As discussed above, the actual direction in which projecting portion 70 of the RDL capture pad 41 projects will depend upon the structure of the die 10.

Although certain embodiments of a WSP die have been described in detail herein, it is to be understood that a WSP die is not limited to such embodiments and such detail and that it may be otherwise constructed and arranged without departing from the spirit and scope of this description. Many alternative embodiments will be apparent to those skilled in the art after reading this disclosure. It is intended that the appended claims be construed to encompass such alternative embodiments, except to the extent limited by the prior art.

What is claimed is:

1. A WSP die comprising:
a redistribution layer (“RDL”) capture pad having an RDL pad outer peripheral edge; and
an under bump metal (“UBM”) pad positioned above said RDL capture pad and having a UBM pad outer peripheral edge positioned partially laterally inwardly of said RDL capture pad outer peripheral edge and positioned partially laterally outwardly of said RDL capture pad outer peripheral edge.

2. The WSP die of claim 1 wherein said RDL capture pad has a smaller area than an area defined by said UBM pad outer peripheral edge.

3. The WSP die of claim 1 wherein said RDL outer peripheral edge comprises a bilaterally symmetrical geometric shape.

4. The WSP die of claim 1 wherein said RDL outer peripheral edge comprises a circular shape.

5. The WSP die of claim 1 wherein said RDL outer peripheral edge comprise an oval shape.

6. The WSP die of claim 1 wherein said UBM pad outer peripheral edge and said RDL capture pad outer peripheral edge have the same shape.

7. The WSP die of claim 1 wherein said portion of said RDL capture pad positioned radially outwardly of said UBM pad outer peripheral edge comprises at least 2.8% of the area of said RDL capture pad.

8. The WSP die of claim 1 wherein said RDL capture pad and said UBM pad outer peripheral edges are both circles and wherein the centers of the RDL capture pad and said UBM pad are offset a distance of between 5% and 12% of the radius of said RDL capture pad.

9. A WSP die comprising:
a redistribution layer (“RDL”) having an RDL pad that has an RDL pad central axis and a RDL pad outer periphery arranged about said RDL pad central axis and
an under bump metal (UBM) pad positioned above said RDL pad, said UBM pad having a UBM pad central axis and a UBM pad outer periphery arranged around said UBM central axis, wherein said UBM pad central axis is laterally offset from said RDL pad central axis.

10. The WSP die of claim 9 wherein said RDL capture pad outer periphery defines an RDL pad area and wherein said UBM pad outer periphery defines a UBM pad area and wherein said UBM pad area is larger than said RDL pad area.

11. A method making a WSP die having relatively low parasitic capacitance and good mechanical integrity comprising:
forming an RDL capture pad with a central axis and a circular outer peripheral edge and an area defined by the circular outer peripheral edge; and
forming above the RDL capture pad a UBM pad having a central axis positioned in parallel, radially offset relationship with the central axis of the RDL capture pad and having an outer peripheral edge defining a UBM circular area that is greater than the area of the RDL capture pad.

12. The method of claim 11 wherein said positioning the RDL capture pad comprises radially offsetting the RDL pad central axis relative the UBM pad central axis in a direction that is dependent on a solder ball that is to be received by the UBM pad.

13. The method of claim 12 wherein said radially offsetting the RDL central axis relative the UBM central axis comprises radially offsetting the RDL axis a distance that is between 5% and 12% of the length of the RDL radius.

14. The method of claim 13, further comprising providing a dielectric layer between axially spaced apart portions of the UBM pad and the RDL capture pad.

15. The method of claim 14 wherein said providing a dielectric layer comprises providing a dielectric layer that extends laterally beyond both the UBM pad and the RDL capture pad.

16. The method of claim 15 wherein said providing a dielectric layer between axially spaced apart portions of the UBM pad and the RDL capture pad comprises providing a polyimide layer.

17. The method of claim 11 wherein forming above the RDL capture pad a UBM pad having a central axis positioned in parallel, radially offset relationship with the central axis of the RDL capture pad and having an outer peripheral edge defining a UBM a circular area that is greater than the area of the RDL capture pad comprises forming a UBM pad having a UBM a circular area that is at least 2.8% larger than the area of the RDL capture pad.

18. The WSP die of claim 2 wherein said area of said UBM pad outer peripheral edge defines and area that is at least 2.8% larger said area of said RDL pad.

19. The WSP die of claim 7 wherein said area of said UBM pad outer peripheral edge defines and area that is at least 2.8% larger said area of said RDL pad.

20. The WSP die of claim 1 wherein a layer of dielectric material is positioned between spaced apart portions of said UBM pad and said RDL capture pad.
